(19) United States
(12) Patent Application Publication
(10) Pub. No.: US 2012/0069498 A1
(43) Pub. Date: Mar. 22, 2012

(54) METAL HOUSING AND FABRICATION METHOD THEREOF

(75) Inventors: ZI-MING TANG, Shenzhen City (CN); FA-GUANG SHI, Shenzhen City (CN)

(73) Assignees: HON HAI PRECISION INDUSTRY CO., LTD., Tu-Cheng,Taipei Hsien (TW); FU TAI HUA INDUSTRY (SHENZHEN) CO., LTD., ShenZhen City, Guangdong Province (CN)

(21) Appl. No.: 12/947,999

(22) Filed: Nov. 17, 2010

(30) Foreign Application Priority Data
Sep. 16, 2010 (CN) 201010283433.4

(51) Int. Cl. H05K 5/00; B21D 11/10

(52) U.S. Cl. 361/679.01; 72/379.4

(57) ABSTRACT

A metal housing includes a bottom shell and a reinforcement frame. The reinforcement frame is interference fitted with the bottom shell. The display screen is fixed on the reinforcement frame. The bottom shell includes a bottom plate and four side plates extended from a periphery of the bottom plate. A thickness of the bottom shell is below 1.2 mm. The reinforcement frame resists the four side plates of the bottom shell. The reinforcement frame includes four reinforcement walls integrally formed with each other.

### BACKGROUND

1. Technical Field

The present disclosure relates to device housings and particularly, to a metal housing of an electronic device and a fabrication method thereof.

2. Description of the Related Art

A typical electronic device usually includes a housing and a display screen fixed on the housing. The housing is usually made of one or more metal materials. A thickness of the housing is reduced to minimize the weight of the electronic device. However, upon impact, the display screen is easily detached from the housing due to the minimal structural strength of the thinner housing.

Therefore, there is room for improvement within the art.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout several views, and all the views are schematic.

FIG. 1 is an assembled, isometric view of one embodiment of a metal housing for an electronic device and a display screen fixed on the metal housing.

FIG. 2 is an exploded, isometric view of the metal housing shown in FIG. 1.

FIG. 3 is an exploded, isometric view of a mold used to assemble the metal housing.

FIG. 4 is a flowchart of fabrication method of the metal housing shown in FIG. 1.

### DETAILED DESCRIPTION

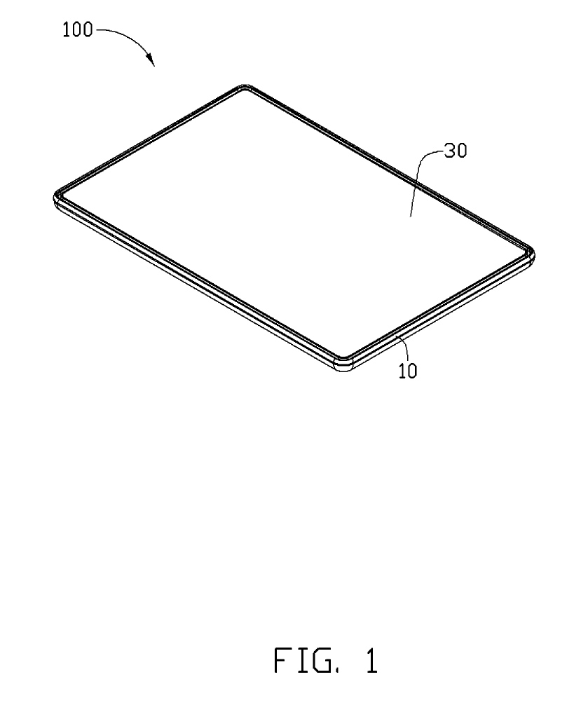

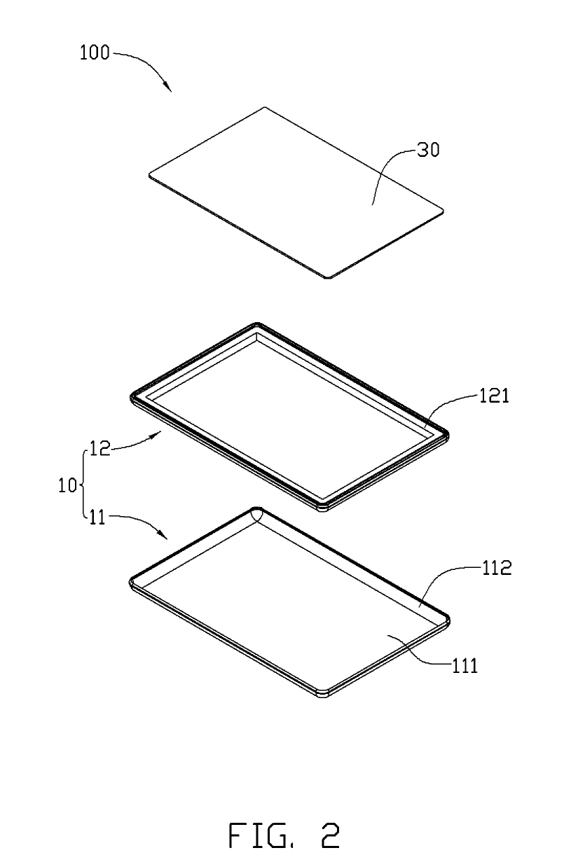

FIGS. 1 and 2 show one embodiment of a metal housing 10 for an electronic device 100 that includes a display screen 30 and other various functional modules (not shown). The other various functional modules are used to implement a variety of appropriate functions such as telephony, playing audio or others. The electronic device 100 can be a touch panel, a cell phone, a MP3 (Moving Picture Experts Group Audio Layer III) player, a PDA (Personal Digital Assistant), a digital photo frame or a liquid crystal display. In the illustrated embodiment, the electronic device 100 is a touch panel device. The metal housing 10 includes a bottom shell 11 and a reinforcement frame 12. The reinforcement frame 12 is fixed to the bottom shell 11 via interference fitting. The display screen 30 is fixed on the reinforcement frame 12.

The bottom shell 11 is substantially rectangular, and includes a bottom plate 111 and four side plates 112. The bottom plate 111 is substantially rectangular. The four side plates 112 extend from a periphery of the bottom plate 111, respectively. Each side plate 112 is substantially curved. A connecting portion of two adjoining side plates 112 is also substantially curved. The bottom shell 11 is aluminum alloy, magnesium alloy, titanium alloy, stainless steel, or other metal. A thickness of the bottom shell 11 is less than 1.2 mm.

The reinforcement frame 12 includes four reinforcement walls 121 connecting in order. The four reinforcement walls 121 are integrally formed on the corresponding side plates 112 of the bottom shell 11. The reinforcement frame 12 is metal such as aluminum alloy, magnesium alloy, titanium alloy, stainless steel, or other.

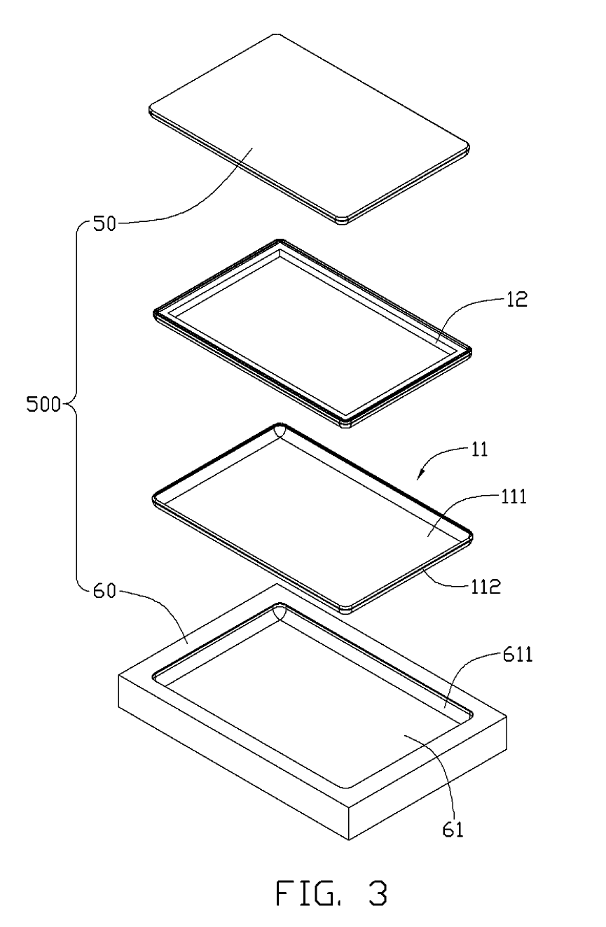

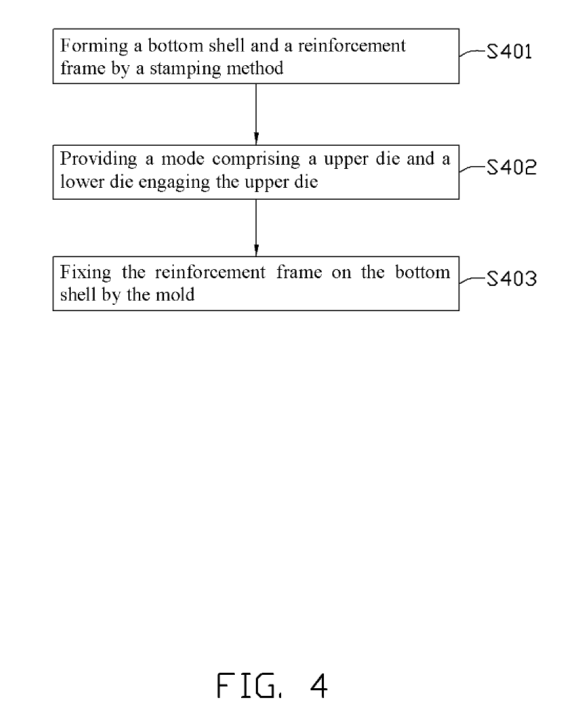

FIGS. 3 and 4 show a fabrication method of the metal housing 10 of the disclosure as follows.

In step S401, a bottom shell 11 and a reinforcement frame 12 are formed by stamping.

In step S402, a mold 500 is provided, and the mold 500 includes an upper die 50 and a lower die 60. In the illustrated embodiment, the upper die 50 is a substantially rectangular plate. The lower die 60 defines a cavity 61 in the center thereof, which is shaped to conform to the bottom shell 11. The cavity 61 has four inner walls 611.

In step S403, the reinforcement frame 12 is fixed on the bottom shell 11 by the mold 500, via interference fit. The bottom shell 11 is received in the cavity 61. The side plates 112 of the bottom shell 11 resist the corresponding inner walls 611. The upper die 50 impels or pushes the reinforcement frame 12 to be received in the bottom shell 11, via interference fitting therewith.

The reinforcement frame 12 is fixed to the bottom shell 11 to increase the structural strength and shock resistance of the metal housing 10. Lowered thickness of the bottom shell 11 allows the reinforcement frame 12 to be assembled to the bottom shell 11 by the mold 500 with protection from damages despite of the thinner profile.

It is to be understood that the bottom plate 111 can also be substantially circular or polygonal. The side plates 112 can also extend perpendicularly to the bottom plate 111.

Finally, while the present disclosure has been described with reference to particular embodiments, the description is illustrative of the disclosure and is not to be construed as limiting the disclosure. Therefore, various modifications can be made to the embodiments by those of ordinary skill in the art without departing from the true spirit and scope of the disclosure as defined by the appended claims.

What is claimed is:

1. A metal housing for an electronic device comprising:
a display screen;
a bottom shell; and
a reinforcement frame, wherein the reinforcement frame is interference fitted with the bottom shell, and the display screen is fixed on the reinforcement frame.

2. The metal housing of claim 1, wherein the bottom shell comprises a bottom plate and four side plates extending from a periphery of the bottom plate, respectively, and the reinforcement frame resisting the four side plates.

3. The metal housing of claim 1, wherein the bottom shell is metal comprising aluminum alloy, magnesium alloy, titanium alloy or stainless steel.

4. The metal housing of claim 1, wherein the reinforcement frame comprises four reinforcement walls integrally formed together.

5. The metal housing of claim 1, wherein the reinforcement frame is a metal comprising aluminum alloy, magnesium alloy, titanium alloy or stainless steel.

6. The metal housing of claim 1, wherein a thickness of the bottom shell is below 1.2 mm.

7. A fabrication method of a metal housing for an electronic device, comprising:
forming a bottom shell and a reinforcement frame by stamping;
providing a mold comprising an upper die and a lower die; and
fixing the reinforcement frame on the bottom shell by the mold.

8. The fabrication method of the metal housing of claim 7, wherein the lower die defines a cavity in the center of the lower die, and the upper die engaging in the cavity via interference fitting.

9. The fabrication method of the metal housing of claim 7, wherein the bottom shell is received in the cavity, the upper die pressing the reinforcement frame to receive in the bottom shell, such that the reinforcement frame is interference fitted with the bottom shell.

10. The fabrication method of the metal housing of claim 7, wherein the bottom shell comprises a bottom plate and four side plates extending from a periphery of the bottom plate, respectively, and the reinforcement frame resisting the four side plates.

11. The fabrication method of the metal housing of claim 7, wherein the bottom shell is metal selected from the group consisting of aluminum alloy, magnesium alloy, titanium alloy and stainless steel.

12. The fabrication method of the metal housing of claim 7, wherein the reinforcement frame comprises four reinforcement walls integrally formed together.

13. The fabrication method of the metal housing of claim 7, wherein the reinforcement frame is metal selected from the group consisting of aluminum alloy, magnesium alloy, titanium alloy and stainless steel.

14. The fabrication method of the metal housing of claim 7, wherein a thickness of the bottom shell is below 1.2 mm.
